(19) United States
(12) Patent Application Publication
(10) Pub. No.: US 2025/0167538 A1
(43) Pub. Date: May 22, 2025

(54) CURRENT BREAKER

(71) Applicant: Panasonic Intellectual Property Management Co., Ltd., Osaka (JP)

(72) Inventor: TAKASHI HIROBE, Osaka (JP)

(21) Appl. No.: 18/722,589

(22) PCT Filed: Jan. 24, 2023
(86) PCT No.: PCT/JP2023/002133

§ 371 Date: Nov. 26, 2024

(30) Foreign Application Priority Data
Feb. 24, 2022 (JP) 2022-027169

(51) Int. Cl. H02H 3/08; B60L 3/04; H02H 1/00

(52) U.S. Cl. CPC H02H 3/08; B60L 3/04; H02H 1/0007

(57) ABSTRACT

A current breaker includes a first measurement unit configured to measure current flowing in a current path, a second measurement unit including an air core coil wound around the current path and configured to measure, by the air core coil, a derivative of the current flowing in the current path, and a driver configured to interrupt the current path by driving a pyro-fuse according to the derivative measured by the second measurement unit.

### TECHNICAL FIELD

The present disclosure relates to a current breaker configured to interrupt a large current flow in a current path when a fault occurs.

### BACKGROUND ART

PTL 1 discloses a device configured to interrupt a large current flow in a current path when a fault occurs by driving a pyro-fuse according to current measured by a shunt resistor.

### CITATION LIST

### Patent Literature

PTL 1: U.S. Pat. No. 10,833,499

### SUMMARY OF INVENTION

The device disclosed in PTL 1 requires a wide current measuring range in order to measure a large current in an abnormal state. As a result, the measurement precision of current in a normal state (current smaller than the large current in the abnormal state) decreases.

A current breaker according to an aspect of the present disclosure is a current breaker configured to interrupt a current path. The current breaker includes: a first measurement unit configured to measure current flowing in the current path; a second measurement unit including an air core coil wound around the current path and configured to measure, by the air core coil, a derivative of the current flowing in the current path; and a driver configured to interrupt the current path by driving a pyro-fuse according to the derivative measured by the second measurement unit.

The current breaker according to the aspect of the present disclosure interrupts a large current in the abnormal state and is also capable of precisely measuring current in the normal state.

### BRIEF DESCRIPTION OF DRAWINGS

FIG. 1A illustrates a current breaker according to Exemplary Embodiment 1.

FIG. 1B is a schematic diagram of a vehicle including the current breaker installed thereto according to Embodiment 1.

FIG. 2 illustrates current flowing in a current path and its derivative.

FIG. 3 illustrates a current measuring range and a measurement precision of a current breaker of a comparative example.

FIG. 4 illustrates a current measuring range and a measurement precision of the current breaker according to Embodiment 1.

FIG. 5 illustrates a winding position of an air core coil of the current breaker according to Embodiment 1.

FIG. 6 illustrates a current breaker according to Exemplary Embodiment 2.

### DESCRIPTION OF EMBODIMENT

Exemplary embodiments of the present disclosure will be detailed below with reference to the drawings.

The following exemplary embodiments describe comprehensive or specific examples. Values, shapes, materials, components, arrangements and positions of the components, connections, and the like in the exemplary embodiments are merely examples and not intended to limit the present disclosure.

### Exemplary Embodiment 1

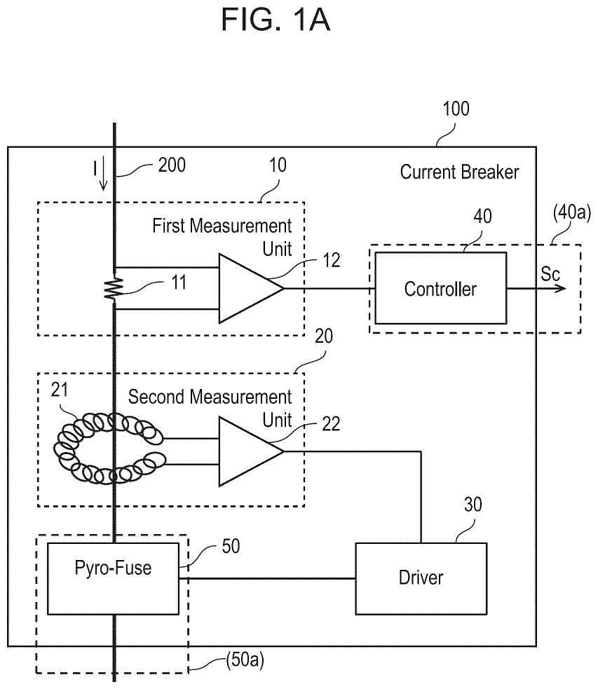

Current breaker 100 according to Exemplary Embodiment 1 will be described below with reference to FIGS. 1A-5.

FIG. 1A illustrates current breaker 100 according to Embodiment 1. FIG. 1B is a schematic diagram of vehicle 500 having current breaker 100 installed thereto.

Current breaker 100 is configured to be installed in, for example, vehicle 500, such as an electric vehicle employing electric power for propulsion. Vehicle 500, such as the electric vehicle, is equipped with high-voltage battery 501 configured to supply power from high-voltage battery 501 to driving load 502, such as a motor, to propel vehicle 500, such as the electric vehicle. Engine electronic control unit (ECU) 503 installed in vehicle 500 controls driving load 502. When an accident occurs, smoke or fire may be generated from vehicle 500 due to a large current caused by a fault, such as a short circuit, in current path 200 connecting high-voltage battery 501 to driving load 502. Current breaker 100 is installed to interrupt current path 200 (specifically, interrupting a large current flowing in the current path when a fault occurs).

Current breaker 100 includes first measurement unit 10, second measurement unit 20, driver 30, controller 40, and pyro-fuse 50. Current breaker 100 has, for example, a processor and a memory. The memory is a read only memory (ROM), a random access memory (RAM), and the like, and is capable of storing a program to be executed by the processor. Driver 30 and controller 40 are implemented by the processor or the like executing the program stored in the memory. Note that driver 30 may also be implemented by an analog circuit such as a comparator.

First measurement unit 10 is a circuit configured to measure current I (current value) flowing in current path 200, and includes, for example, shunt resistor 11 and amplifier 12.

Shunt resistor 11 is inserted in current path 200 for measuring current I flowing in current path 200. The recitation “shunt resistor 11 is inserted in current path 200” is intended to mean, for example, “current path 200 is cut and shunt resistor 11 is inserted between the cut points of current paths 200 so as to connect the cut points of current path 200.” Shunt resistor 11 is configured to measure current I flowing in current path 200 and outputs as a voltage by converting current I flowing in current path 200 to the voltage. Shunt resistor 11 is available at low cost, has a good linearity, and is capable of measuring currents ranging from a direct current to several megahertz (MHz) without being saturated magnetically. A Hall element may be employed instead of shunt resistor 11.

The Hall element is an element for measuring current I flowing in current path 200. Unlike shunt resistor 11, the Hall element is capable of measuring current I flowing in current path 200 without being inserted in current path 200. While details of the Hall element will be omitted, the Hall element measures and outputs a voltage corresponding to a magnetic field generated responsive to current I flowing in current path 200 passing through a magnetic core. The Hall element measures current I from a direct current to several MHz while being insulated from the current. An example including Hall element 13 will be described later in Exemplary Embodiment 2.

Since a signal output from shunt resistor 11 or the Hall element is a faint signal, amplifier 12 amplifies the signal. The signal amplified by amplifier 12 is output to controller 40. First measurement unit 10 may not necessarily include amplifier 12. In this case, the signal output from shunt resistor 11 may be output to controller 40 per se.

For example, a measuring range of current I of first measurement unit 10 is set to a normal use range, and first measurement unit 10 is used for measuring current I in the normal state. First measurement unit 10 precisely measures current I in the normal state. The normal use range refers to a range of current I allowable to flow in current path 200 in the normal state. The normal state refers to a state without a fault, such as a short circuit, and vehicle 500 is used in a normal way.

Controller 40 obtains current I flowing in current path 200 measured by first measurement unit 10, and outputs control signal Sc to perform control related to vehicle 500 according to the obtained value of current I. For example, controller 40 outputs control signal Sc to other controllers, such as ECU 503. ECU 503 controls, for example, driving load 502 of vehicle 500 based on control signal Sc, the operation by passenger 504, and other signals including a signal from a sensor.

Second measurement unit 20 includes air core coil 21 and amplifier 22, and is a circuit for measuring, by air core coil 21, a derivative (dI/dt) of current I flowing in current path 200.

Air core coil 21 is wound around current path 200, and is a coil for measuring the derivative of current I flowing in current path 200. Air core coil 21 is configured to measure current I with large value without being saturated magnetically but only measure an alternating current (AC) current while being affected by an external magnetic field. When a large current, i.e., current I with large value, flows in current path 200 due to a fault, current I flowing in current path 200 largely changes. In other words, large current I instantaneously flows (i.e., instantaneous current) in current path 200. A magnetic field generated by this instantaneous current causes an induced electromotive force in air core coil 21. The induced electromotive force is output from air core coil 21 as a time derivative of current I flowing in current path 200.

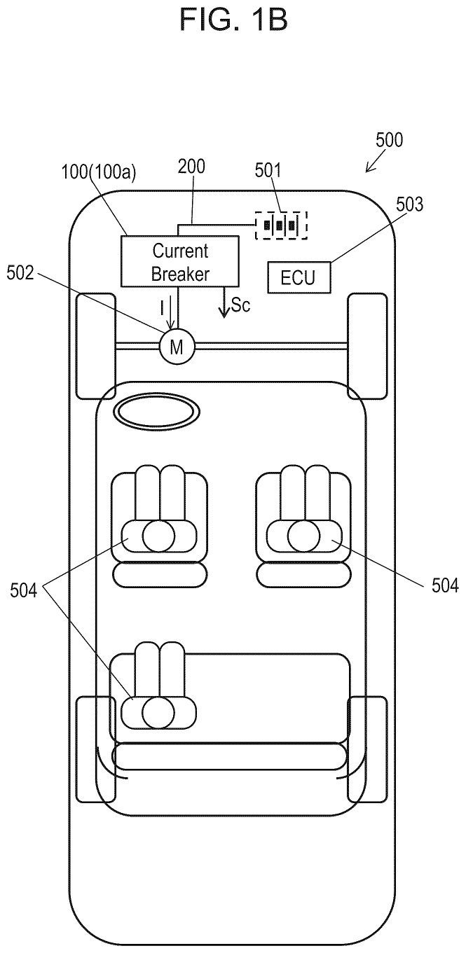

FIG. 2 illustrates current I flowing in current path 200 and a derivative of current I. FIG. 2(a) is a graph showing current I flowing in current path 200, and FIG. 2(b) is a graph showing the derivative of current I flowing in current path 20.

As illustrated in FIG. 2(a), when current I flowing in current path 200 suddenly changes due to a fault, air core coil 21 outputs the derivative of current I flowing in current path 2 as illustrated in FIG. 2(b).

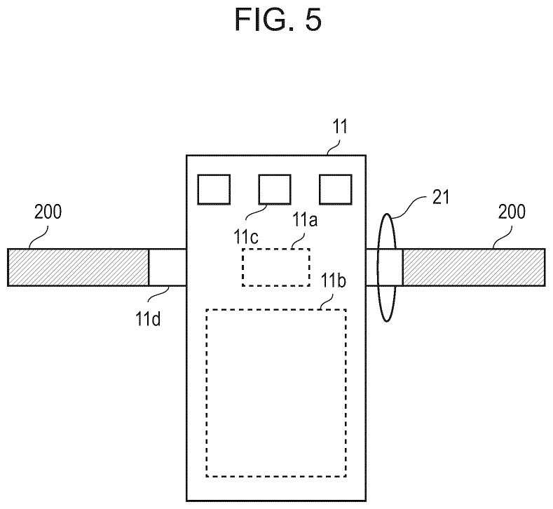

For example, air core coil 21 may be wound around shunt resistor 11. This will be described with reference to FIG. 5.

FIG. 5 illustrates an example of a winding position of air core coil 21.

For example, shunt resistor 11 includes resistor 11a, voltage detecting circuit 11b, output terminal 11c, and connection terminal 11d. For example, resistor 11a and voltage detecting circuit 11b are provided inside a housing of shunt resistor 11. In addition, a heat sink (not illustrated) is provided in shunt resistor 11 because heat will be generated when a large current flows. Resistor 11a is inserted in current path 200 so as to generate a voltage responsive to current I flowing in current path 200. Resistor 11a has a small resistance value of about several milliohms (mΩ). Voltage detecting circuit 11b is a circuit for detecting the voltage generated across resistor 11a. Output terminal 11c is a terminal configured to output the voltage detected by voltage detecting circuit 11b. Output terminal 11c is connected to amplifier 12, controller 40, or the like. Connection terminal 11d is a terminal connecting current path 200 to resistor 11a.

For example, air core coil 21 may be wound around connection terminal 11d of shunt resistor 11. Shunt resistor 11 is inserted in current path 200 as a part of current path 200. Therefore, when air core coil 21 is wound around shunt resistor 11, it can also be said that air core coil 21 is wound around current path 200. Air core coil 21 may be wound around current path 200 near shunt resistor 11.

A type of air core coil 21 is not particularly limited. For example, air core coil 21 may be a Rogowsky coil. Air core coil 21 which is the Rogowsky coil allows the derivative of current I flowing in current path 200 to pass through an integrator so as to output a signal proportional to current I flowing in current path 200.

Since the signal output from air core coil 21 may be a faint signal, the signal is amplified by amplifier 22. However, second measurement unit 20 may not include amplifier 22. In this case, the signal itself output from air core coil 21 is output to driver 30.

Driver 30 interrupts current path 200 by driving pyro-fuse 50 according to the derivative measured by second measurement unit 20. More specifically, driver 30 drives pyro-fuse 50 to interrupt current I with large value flowing in current path 200 in the abnormal state. In other words, driver 30 drives pyro-fuse 50 to interrupt a short-circuit current generated in current path 200. For example, driver 30 determines whether or not the derivative measured by second measurement unit 20 exceeds a threshold (threshold for the derivative) for driving pyro-fuse 50. When the derivative exceeds the threshold, driver 30 outputs, to pyro-fuse 50, a drive signal for driving pyro-fuse 50. Pyro-fuse 50 receiving the drive signal instantaneously interrupts current path 200.

As described above, current breaker 100 is configured to interrupt current path 200, and includes first measurement unit 10 configured to measure current I flowing in current path 200, second measurement unit 20 including air core coil 21 wound around current path 200 and configured to measure, by air core coil 21, the derivative of current I flowing in current path 200, and a driver configured to interrupt current path 200 by driving pyro-fuse 50 according to the derivative measured by second measurement unit 20.

In this configuration, current I in the normal state is precisely measured by setting, to the normal use range, the measuring range of current I of first measurement unit 10, and first measurement unit 10 measures current I in the normal state. On the other hand, second measurement unit 20 includes air core coil 21 configured to measure a large current. Thus, when a fault, such as a short circuit, occurs, a large current is interrupted in the abnormal state by measuring the large current using second measurement unit 20.

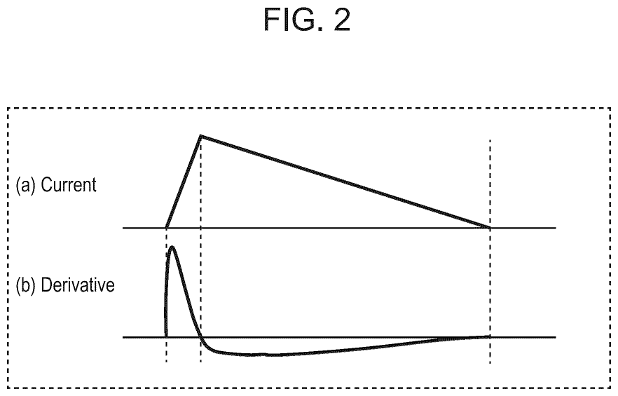

FIG. 3 is a diagram illustrating measuring range MR0 and measurement precision of current according to a comparative example.

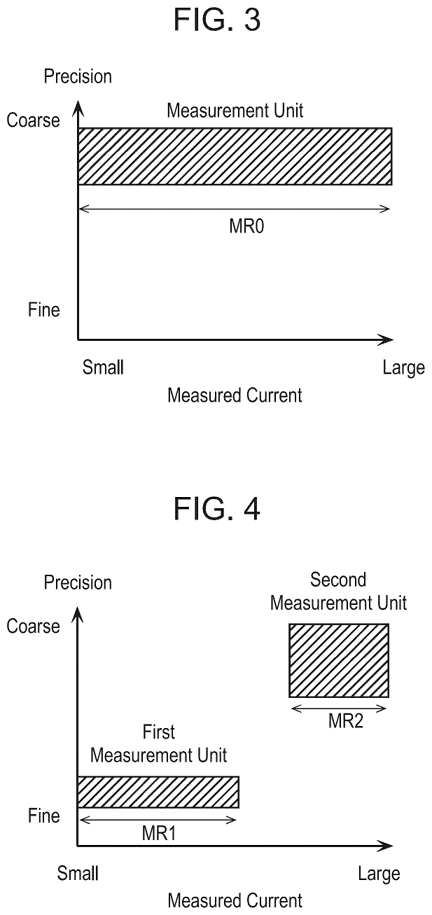

FIG. 4 is a diagram illustrating measuring ranges MR1 and MR2 and measurement precision of current I according to Exemplary Embodiment 1.

The comparative example is an example of measuring current I in the normal state and current I in the abnormal state by a single measurement unit. The comparative example shown in FIG. 3 has a coarse measurement precision because the single measurement unit needs to measure current I in broad range MR0 from current I in the normal state to current I with large value in the abnormal state.

On the other hand, in accordance with Embodiment 1, as illustrated in FIG. 4, first measurement unit 10 focuses on measuring current I in range MR1 in the normal state, and second measurement unit 20 measures large current I in range MR2 in the abnormal state. Thus, fine measurement precision of current I is provided in the normal state and also measurement of large current I and interruption are feasible in the abnormal state. In accordance with Embodiment 1, an upper limit of measuring range MR2 of second measurement unit 20 is higher than an upper limit of measuring range MR1 of first measurement unit 10. In accordance with Embodiment 1, a lower limit of measuring range MR2 of second measurement unit 20 is higher than the upper limit of measuring range MR2 of first measurement unit 10. First measurement unit 10 has a finer measurement precision than a measurement precision of second measurement unit 20. In other words, the minimum value of a difference between current values mutually distinguishable measured by first measurement unit 10 is smaller than the minimum value of a difference between current values mutually distinguishable measured by second measurement unit 20.

As described above, the breaker according to Embodiment 1 is capable of interrupting large current I in the abnormal state and is capable of measuring current I with high precision in the normal state.

In the case that pyro-fuse 50 is driven based on a value of current I, instead of the derivative of current I flowing in current path 200, pyro-fuse 50 is driven to interrupt large current I flowing in current path 200 in the abnormal state when current I flowing in current path 200 increases due to occurrence of a fault and reaches the threshold (threshold for the value of current I) for driving pyro-fuse 50. However, in this case, it takes time until current I flowing in current path 200 reaches the threshold, and the large current may flow to components configuring current breaker 100. To ensure the operation reliability against the large current, components configuring current breaker 100 have large sizes.

On the other hand, according to Embodiment 1, when pyro-fuse 50 is driven responsive to the derivative of current I flowing in current path 200, pyro-fuse 50 is driven by an amount of change of current I flowing in current path 200. When a fault, such as a short circuit, occurs, the amount of change of current I flowing in current path 200 increases in an initial stage of transition to a large value. Thus, pyro-fuse 50 is driven in the initial stage. Accordingly, components configuring current breaker 100 do not necessarily have large sizes in order to ensure the operation reliability against the large current, and current breaker 100 accordingly has a small size.

Since air core coil 21 outputs the derivative of current I flowing in current path 200, software or the like for calculating the derivative of current I flowing in current path 200 is not necessary. The derivative is output just by providing hardware, such as air core coil 21.

For example, first measurement unit 10 includes shunt resistor 11 inserted in current path 200 to measure current I flowing in current path 200, and air core coil 21 may be wound around shunt resistor 11.

Shunt resistor 11 includes voltage detecting circuit 11b, the heat sink, and output terminal 11c, in addition to resistor 11a. Shunt resistor 11 thus has a large size, and hardly allow another current path disposed near shunt resistor 11. On the other hand, since air core coil 21 has a characteristic of being readily affected by an external magnetic field, air core coil 21 may not precisely measure a magnetic field generated by current path 200 (i.e., current flowing in current path 200) due to the effect of external magnetic field generated by another current path when a current path other than current path 200 is arranged near air core coil 21. Air core coil 21 wound around shunt resistor 11 around which another current path is unlikely arranged, the effect on air core coil 21 due to the external magnetic field generated by another current path can be reduced.

### Exemplary Embodiment 2

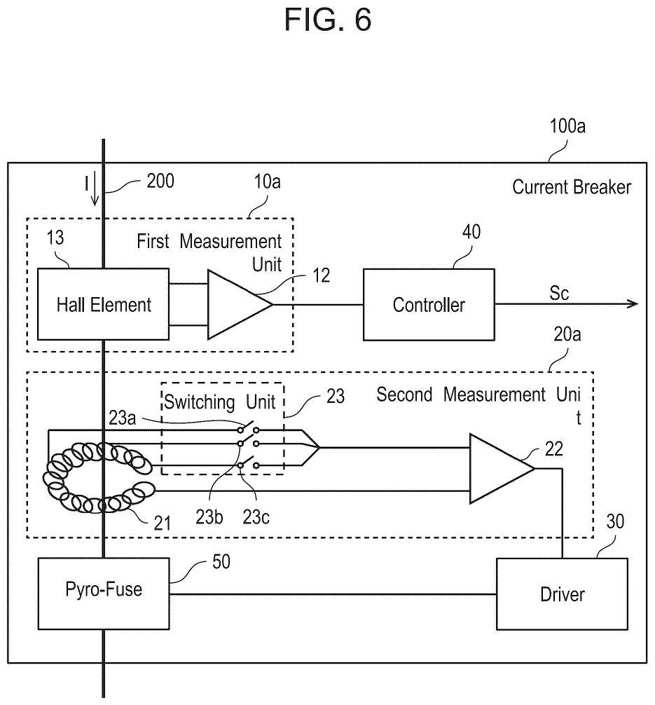

Next, current breaker 100a according to Exemplary Embodiment 2 will be described with reference to FIG. 6.

FIG. 6 is a configuration diagram illustrating current breaker 100a according to Exemplary Embodiment 2.

Current breaker 100a is different from current breaker 100 according to Embodiment 1 in that first measurement unit 10a is provided instead of first measurement unit 10 and second measurement unit 20a instead of second measurement unit 20. Other points are same as those in Embodiment 1, and thus their description will be omitted. First measurement unit 10a and second measurement unit 20a will be described mainly in differences from first measurement unit 10 and second measurement unit 20.

First measurement unit 10a is a circuit configured to measure current I flowing in current path 200, and includes, for example, Hall element 13 and amplifier 12. A shunt resistor may be provided, instead of Hall element 13, in accordance with Embodiment 2.

Second measurement unit 20a includes air core coil 21, amplifier 22, and switching unit 23, and is a circuit configured to measure, by air core coil 21, a derivative of current I flowing in current path 200.

Switching unit 23 is configured to switch an inductance value of air core coil 21. For example, switching unit 23 includes switches 23a, 23b, and 23c. As illustrated in FIG. 6, respective one ends of switches 23a, 23b, and 23c are connected to driver 30 (here, connected to driver 30 via amplifier 22), and the respective other ends are connected to different points of air core coil 21. When switch 23a is electrically connected and switches 23b and 23c are electrically disconnected, a portion of air core coil 21 from a point connected to switch 23a toward respective points connected to switches 23b and 23c is invalidated, thereby decreasing the inductance value of air core coil 21. When switch 23c is electrically connected and switches 23a and 23b are electrically disconnected, a portion of air core coil 21 up to a point connected to switch 23c is validated, thereby increasing the inductance value of air core coil 21.

For example, vehicle 500 including current breaker 100a has a function of detecting the state of vehicle 500 or the presence of passenger 504 in vehicle 500. For example, vehicle 500 detects, as the state of vehicle 500, whether vehicle 500 travels or stops. Vehicle 500 may detect whether vehicle 500 travels or stops by using, for example, information acquired by engine ECU 503 installed in vehicle 500 or information acquired by an acceleration sensor installed in vehicle 500. For example, the presence of passenger 504 in vehicle 500 is detectable by using information acquired by a human detection sensor installed in vehicle 500. Methods of detecting the state of vehicle 500 or the presence of passenger 504 in vehicle 500 are not particularly limited thereto.

Switching unit 23 acquires, from vehicle 500, information on the state of vehicle 500 or the presence of passenger 504 in vehicle 500, and switches the inductance value of air core coil 21 based on the state of vehicle 500 or the presence of passenger 504 in vehicle 500. For example, switching unit 23 is switched to cause the inductance value of the air core coil to be larger when vehicle 500 travels than when vehicle 500 stops. For example, switching unit 23 is switched to cause the inductance value of air core coil 21 to be larger when passenger 504 is present in vehicle 500 than when passenger 504 is absent in vehicle 500.

For example, when vehicle 500 stops and passenger 504 is absent in vehicle 500, switching unit 23 turns on switch 23a and thus off switches 23b and 23c. In this case, air core coil 21 has the smallest inductance value.

For example, when vehicle 500 stops and passenger 504 is present in vehicle 500, switching unit 23 turns on switch 23b and turns off switches 23a and 23c. In this case, the inductance value of air core coil 21 is larger than the inductance value when vehicle 500 stops and passenger 504 is absent in vehicle 500.

For example, when vehicle 500 travels, switching unit 23 turns on switch 23c and turns off switches 23a and 23b. In this case, the inductance value of air core coil 21 is larger than the inductance value when vehicle 500 stops and passenger 504 is present in passenger 500.

As described above, second measurement unit 20a includes switching unit 23 configured to switch the inductance value of air core coil 21. For example, current breaker 100a is installed in vehicle 500, and switching unit 23 may switch the inductance value of air core coil 21 according to the state of vehicle 500 or the presence of passenger 504 in vehicle 500.

The switching of the inductance value of air core coil 21 changes the induced electromotive force, generated in air core coil 21 according to current I flowing in current path 200, responsive to the derivative of current I (specifically, the inductance value of air core coil 21 and the derivative of current I flowing in current path 200: V=Lx (dI/dt)). For example, the measurement unit determines whether or not to drive pyro-fuse 50 based on a threshold of the induced electromotive force. Accordingly, pyro-fuse 50 is readily driven or hardly driven according to the inductance value of air core coil 21 switched according to the situation, such as the state of vehicle 500 or the presence of passenger 504 in vehicle 500. In other words, large current I flowing in current path 200 in the abnormal state is quickly interrupted or hardly interrupted depending on the situation. For example, driving sensitivity of pyro-fuse 50 is increased by switching the inductance value to increase the inductance value.

For example, switching unit 23 may be switched to cause the inductance value of air core coil 21 to be larger when vehicle 500 travels than when vehicle 500 stops. Or, switching unit 23 may be switched to cause the inductance value of air core coil 21 to be larger when passenger 504 is present in vehicle 500 than when passenger 504 is absent in vehicle 500.

In the above configuration, pyro-fuse 50 is more readily driven when vehicle 500 travels than when vehicle 500 stops. Thus, large current I flowing in current path 200 in the abnormal state is interrupted quickly. Still more, when passenger 504 is present in vehicle 500, pyro-fuse 50 may be more readily driven than when passenger 504 is absent in vehicle 500, and thus, large current I flowing in current path 200 in the abnormal state is hardly interrupted. In this way, large current I flowing in current path 200 in the abnormal state can be interrupted quickly in situations where damage is likely to spread such as when vehicle 500 is traveling or passenger 504 is present in vehicle 500.

### Other Exemplary Embodiment

The above exemplary embodiments are described to illustrate a technology disclosed in the present disclosure. However, the technology disclosed in the present disclosure is not limited thereto, and changes, replacement, additions, omissions or the like made in the exemplary embodiments are embraced therein. For example, modified examples below are included in the exemplary embodiments of the present disclosure.

For example, in the above exemplary embodiments, current breakers 100 and 100a include pyro-fuse 50. However, current breakers 100 and 100a may not necessarily include pyro-fuse 50. In other words, device 50a other than current breakers 100 and 100a may include pyro-fuse 50 (see FIG. 1).

For example, in the above exemplary embodiments, current breakers 100 and 100a include controller 40. However, current breakers 100 and 100a may not necessarily include controller 40. In other words, device 40a other than current breakers 100 and 100a may include controller 40 (see FIG. 1).

For example, in the above exemplary embodiments, current breakers 100 and 100a include the processor and the memory. However, current breakers 100 and 100a may not necessarily include the processor and the memory. Current breakers 100 and 100a may be implemented by an analog circuit and the like.

Other embodiments obtained by various modifications to the exemplary embodiments intended by those skilled in the art and any combinations of components and functions of the exemplary embodiments without departing from the gist of the present disclosure are embraced in the present disclosure.

### INDUSTRIAL APPLICABILITY

The present disclosure is applicable to a device that interrupts a large current flowing in the current path in the abnormal state.

### REFERENCE MARKS IN THE DRAWINGS

10, 10a first measurement unit
11 shunt resistor
11a resistor
11b voltage detecting circuit
11c output terminal
11d connection terminal
12, 22 amplifier
13 Hall element
20, 20a second measurement unit
21 air core coil
23 switching unit
23a, 23b, 23c switch
30 driving nit
40 controller
50 pyro-fuse
100, 100a current breaker
200 current path

1. A current breaker configured to interrupt a current path, the current breaker comprising:
a first measurement unit configured to measure current flowing in the current path;
a second measurement unit including an air core coil wound around the current path, the second measurement unit being configured to measure, by the air core coil, a derivative of the current flowing in the current path; and
a driver configured to interrupt the current path by driving a pyro-fuse according to the derivative measured by the second measurement unit.

2. The current breaker of claim 1, wherein the second measurement unit further includes a switching unit configured to switch an inductance value of the air core coil.

3. The current breaker of claim 2, wherein
the current breaker is configured to be installed in a vehicle, and
the switching unit configured to switch the inductance value of the air core coil according to a state of the vehicle or a presence of a passenger in the vehicle.

4. The current breaker of claim 3, wherein the switching unit configured to switch the inductance value of the air core coil to cause the inductance value to be larger when the vehicle travels than when the vehicle stops.

5. The current breaker of claim 3 or 4, wherein the inductance value of the air core coil is switched to be larger when the passenger is present in the vehicle than when the passenger is absent in the vehicle.

6. The current breaker of any one of claims 1 to 5, wherein
the first measurement unit includes a shunt resistor inserted in the current path, the shunt resistor being for measuring the current flowing in the current path, and
the air core coil is wound around the shunt resistor.

7. A vehicle comprising:
the current breaker of any one of claims 1, 2, and 6; and
a vehicle body having the current breaker installed thereto, wherein
the switching unit of the current breaker is configured to switch an inductance value of the air core coil according to a state of the vehicle or a presence of a passenger in the vehicle.

8. The vehicle of claim 7, wherein the switching unit is configured to switch the inductance value of the air core coil to cause the inductance value to be larger when the vehicle travels than when the vehicle stops.

9. The vehicle of claim 7 or 8, wherein the inductance value of the air core coil is switched to be larger when the passenger is present in the vehicle than when the passenger is absent in the vehicle.
